(19) United States
(12) Patent Application Publication
(10) Pub. No.: US 2025/0256319 A1
(43) Pub. Date: Aug. 14, 2025

(54) VENTILATED VEHICLE PROTECTION DEVICE & METHOD OF MANUFACTURE

(71) Applicant: Scrape Armor, Inc., Bellevue, WA (US)

(72) Inventor: Scott Whitehead, Bellevue, WA (US)

(21) Appl. No.: 18/896,544

(22) Filed: Sep. 25, 2024

Related U.S. Application Data
(60) Provisional application No. 63/585,173, filed on Sep. 25, 2023.

(51) Int. Cl. B21D 28/26; B23K 26/38; B60R 19/52

(52) U.S. Cl. CPC B21D 28/26; B23K 26/38; B60R 19/52; B60R 2019/525

(57) ABSTRACT

A device for protecting vulnerable portions of a high-performance motor-vehicle radiator while preserving adequate airflow for cooling is disclosed. A method of manufacturing this device efficiently at scale is disclosed.

### COPYRIGHT NOTICE

This disclosure is protected under United States and/or International Copyright Laws. © 2021-2024. All Rights Reserved. A portion of the disclosure of this patent document contains material which is subject to copyright protection. The copyright owner has no objection to the facsimile reproduction by anyone of the patent document or the patent disclosure, as it appears in the Patent and/or Trademark Office patent file or records, but otherwise reserves all copyrights whatsoever.

### PRIORITY CLAIM

This application claims priority to U.S. Patent Application No. 63/585,173 filed Sep. 25, 2023, the entirety of which is hereby incorporated by reference as if fully set forth herein.

### BACKGROUND

Traditionally, high performance and value vehicles have maximized air flow to certain portions of their vehicles at the expense of protection, durability, and sometimes even aesthetics. This invention improves protection and durability of vulnerable components, yet preserves optimal airflow and aesthetics.

### BRIEF DESCRIPTION OF THE DRAWING FIGURES

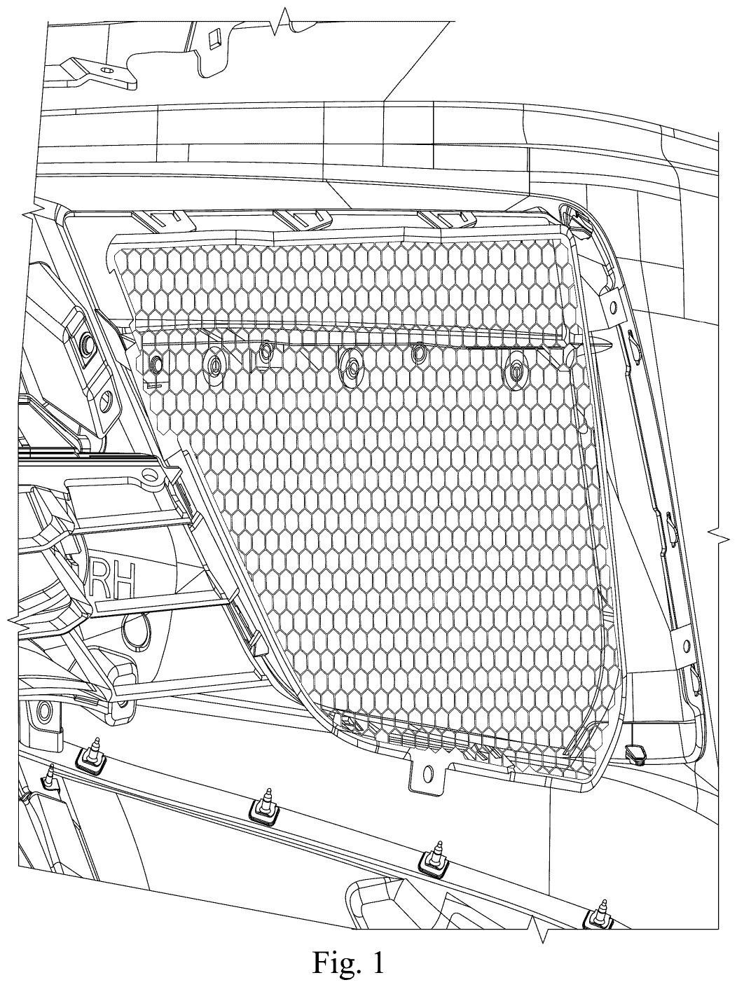

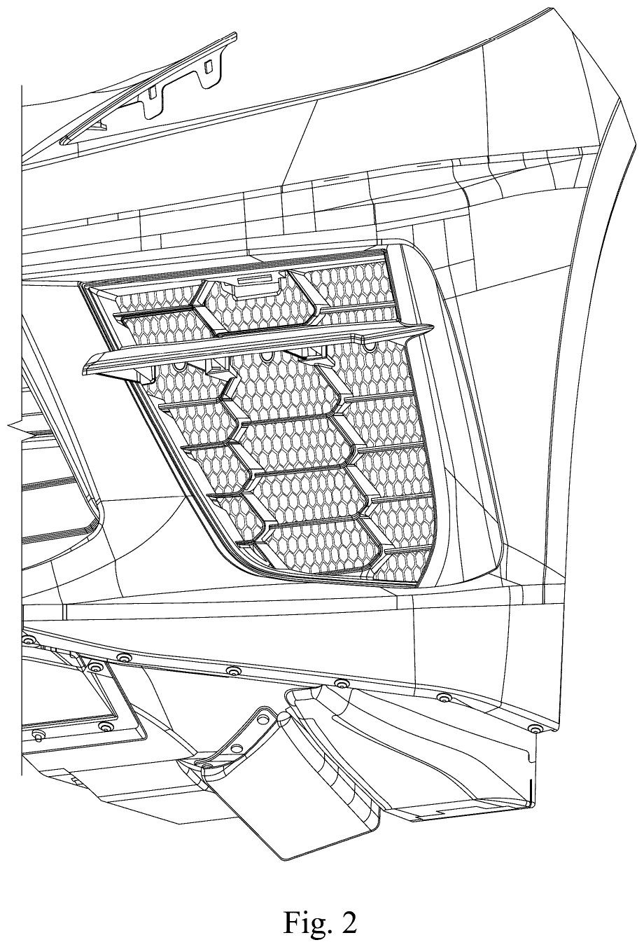

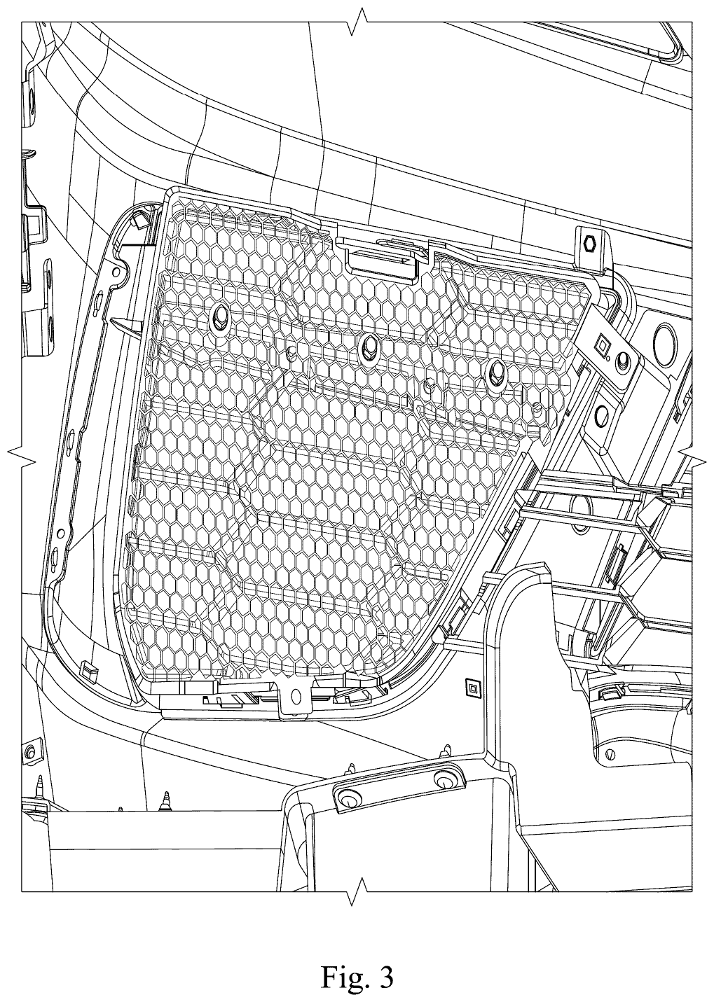

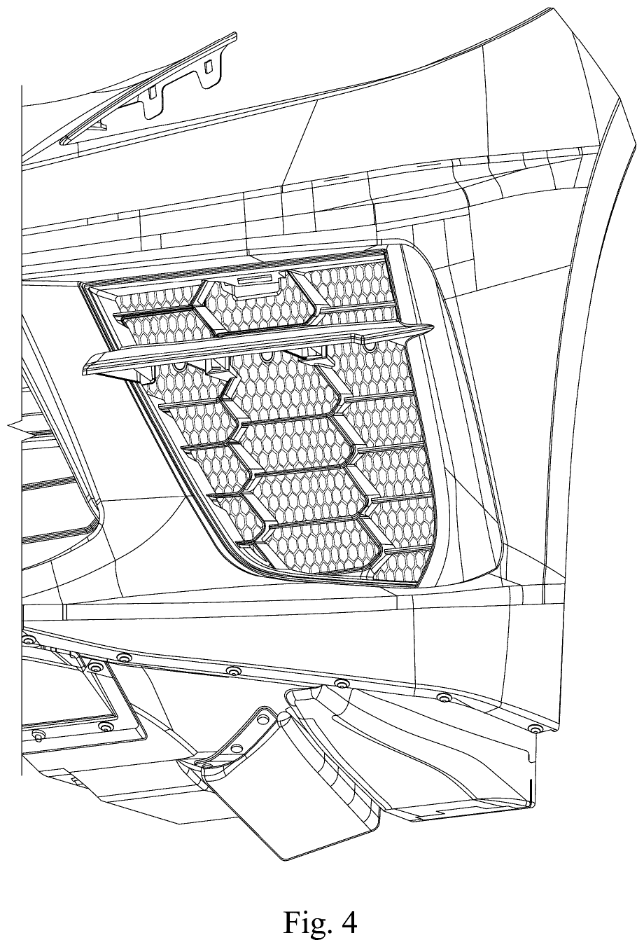

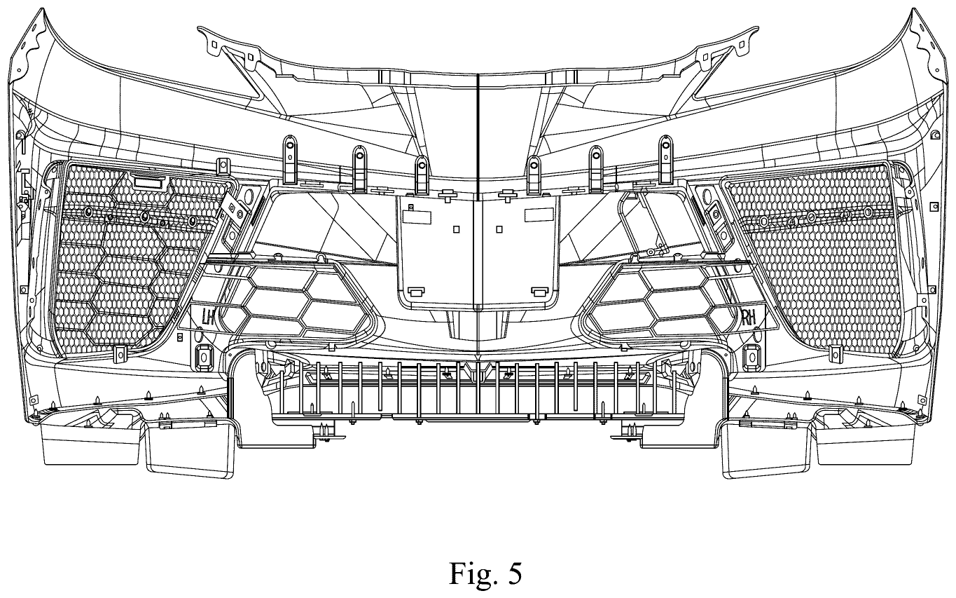

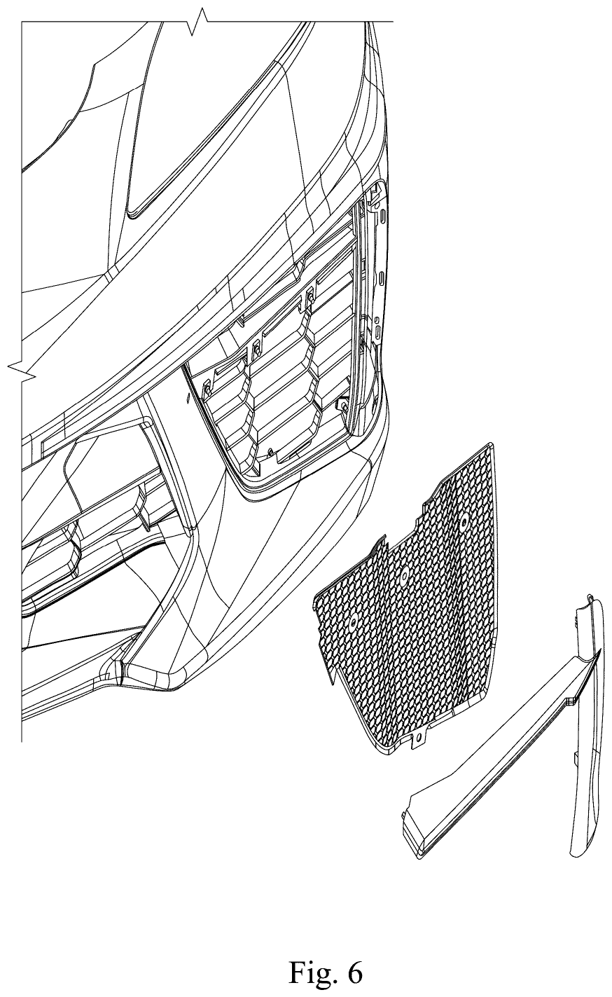

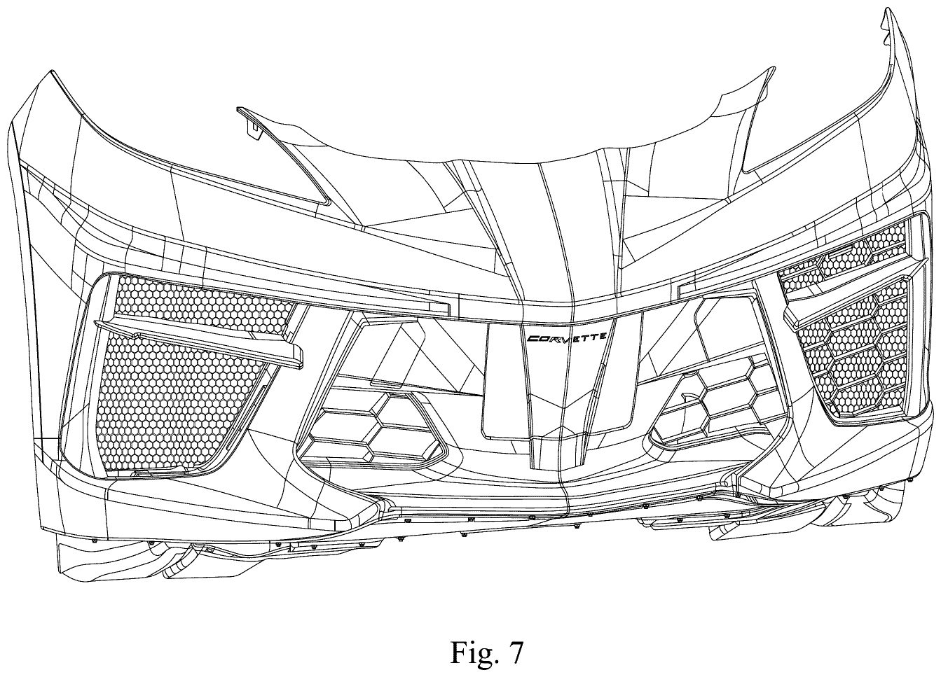

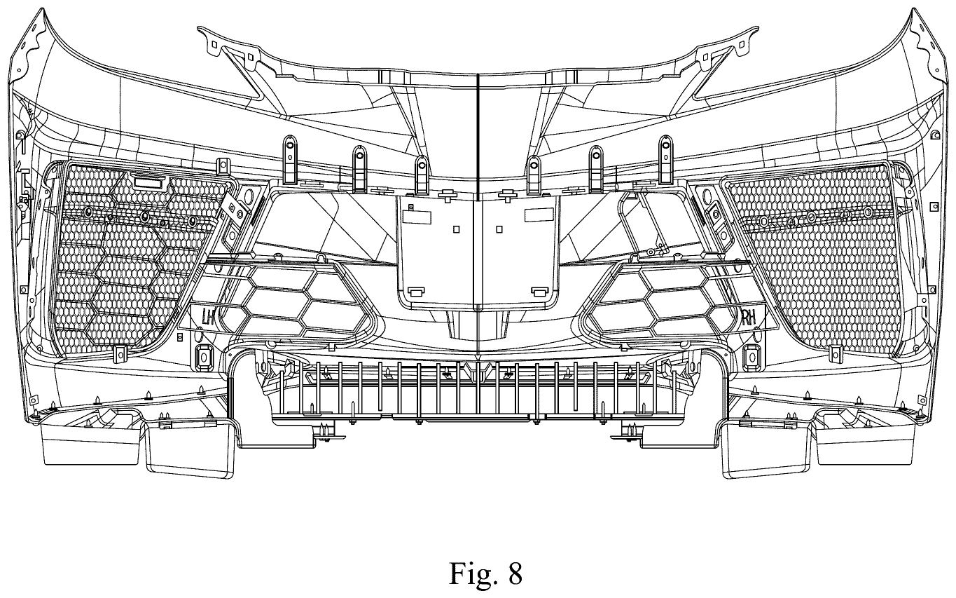

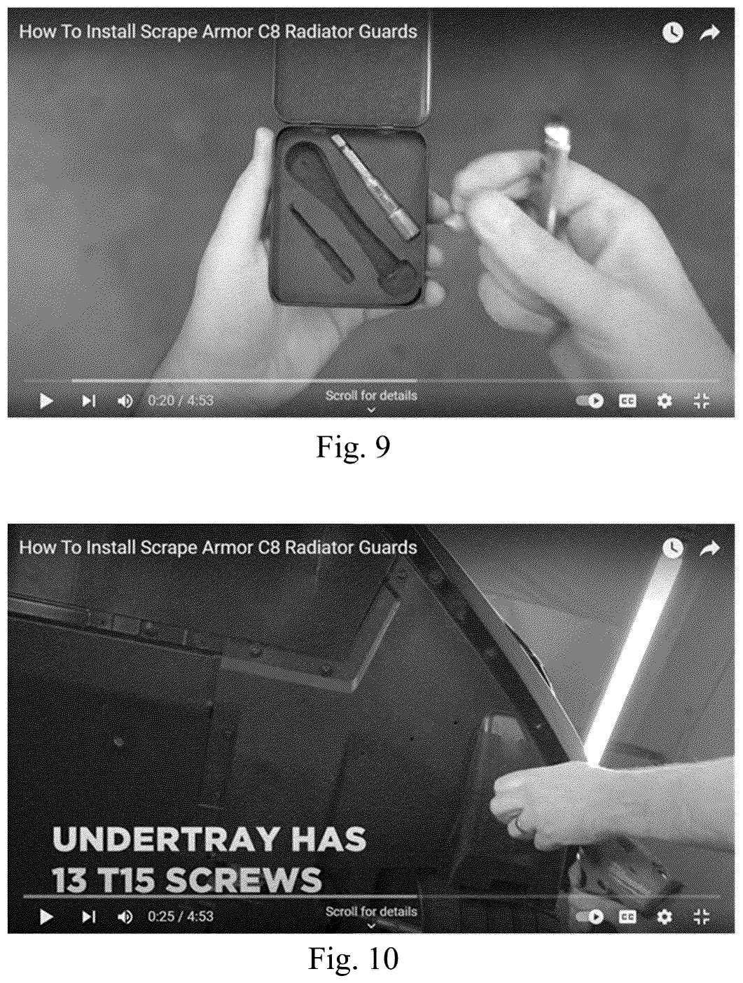

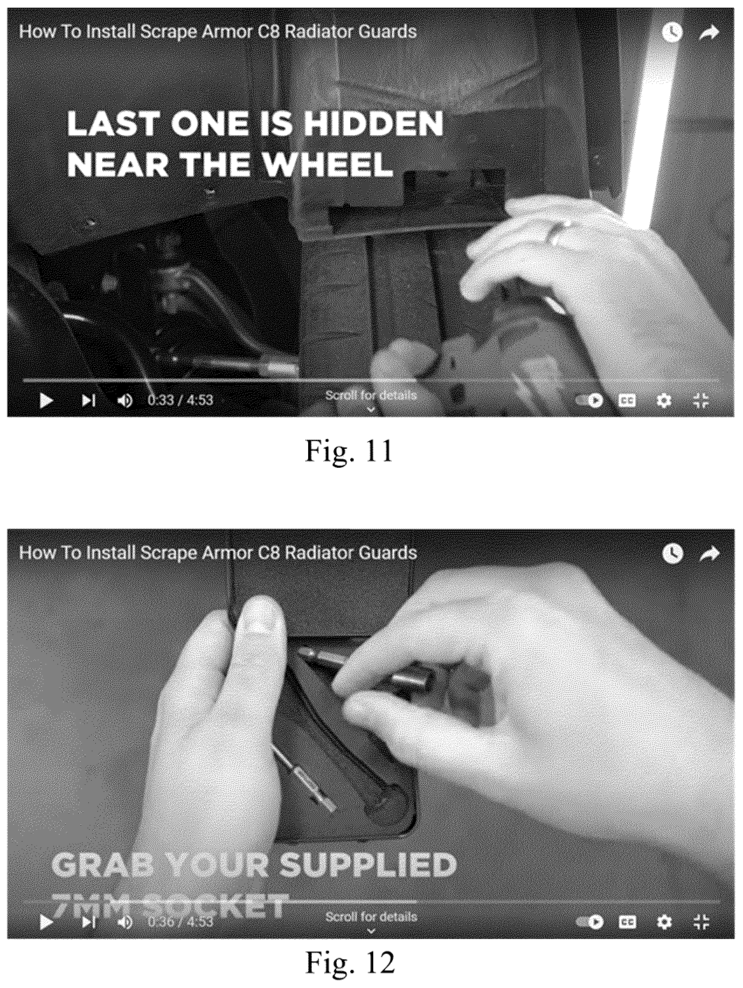

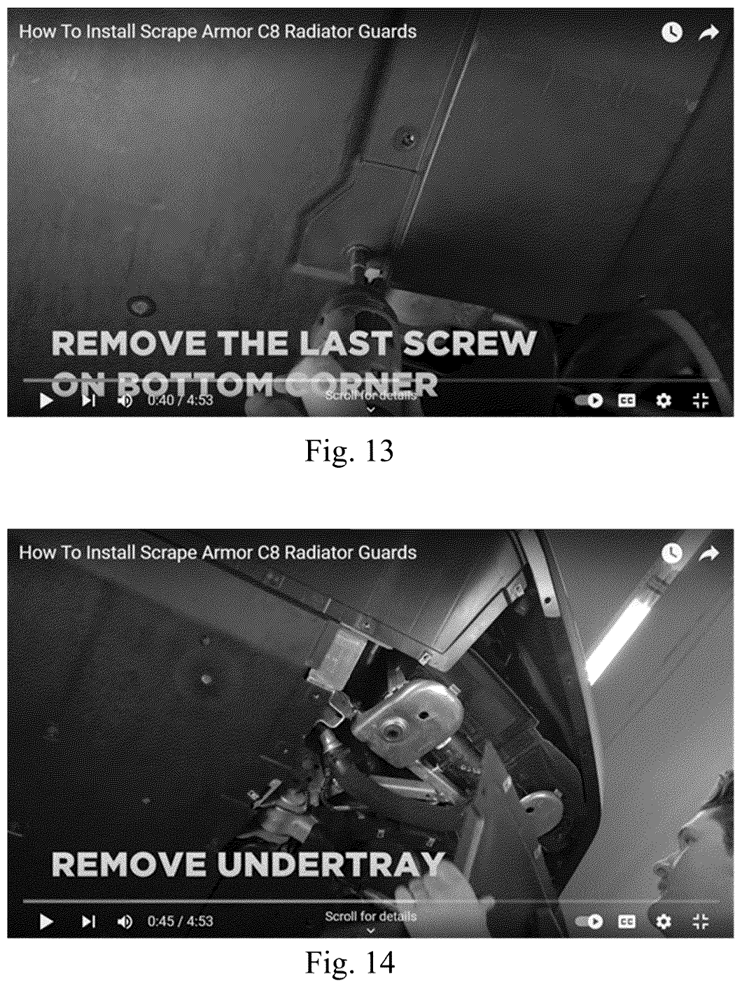

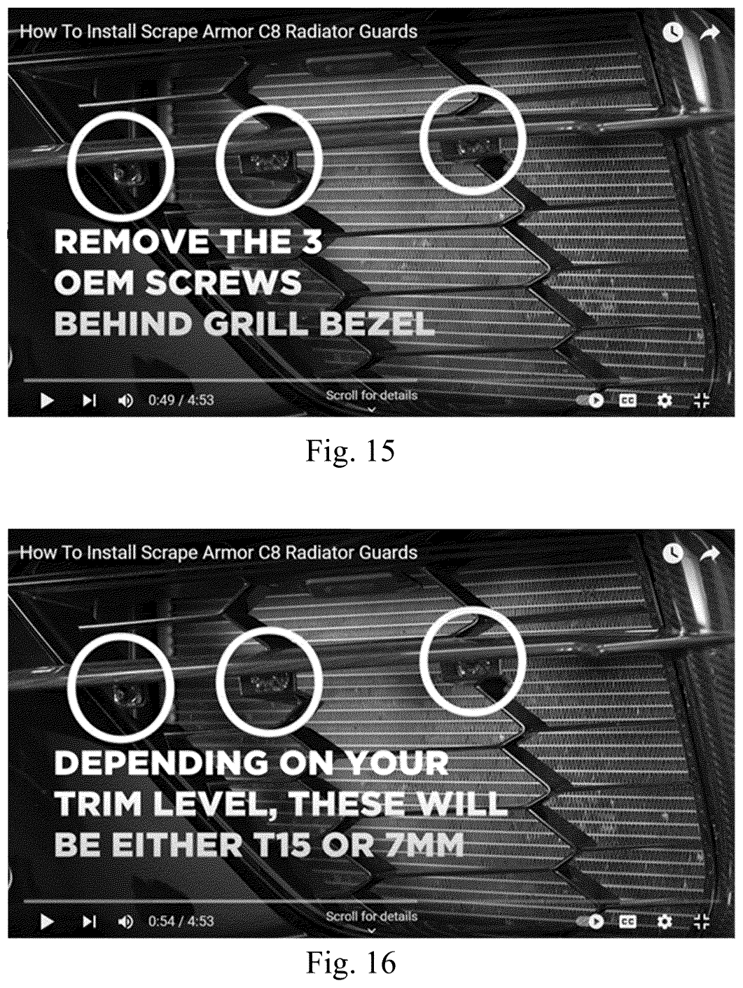

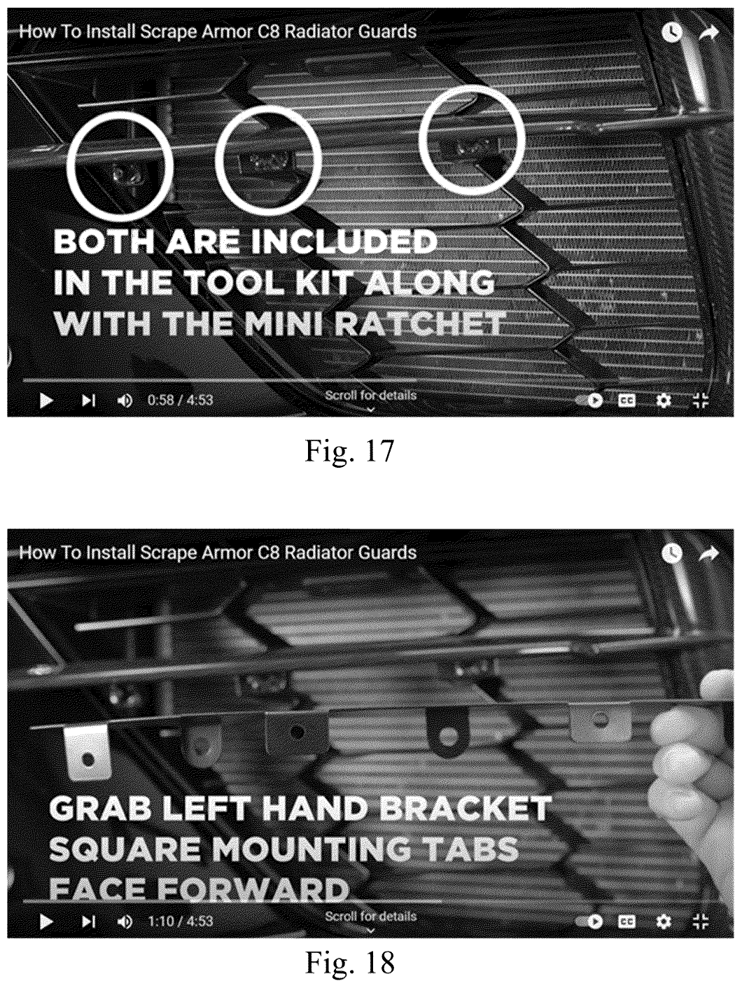

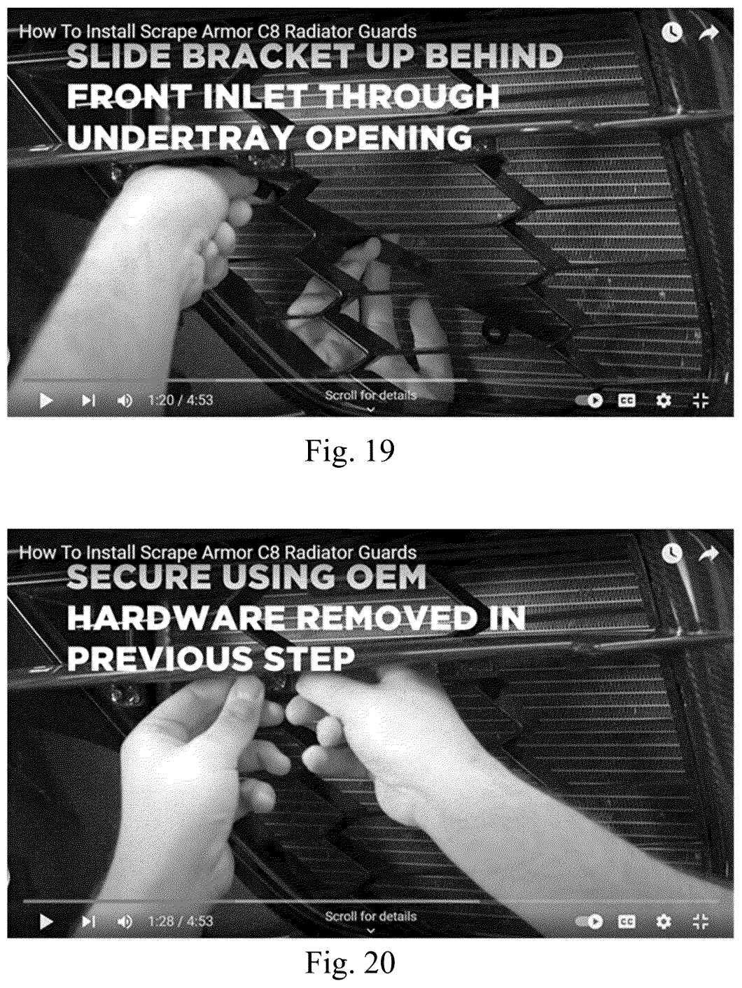

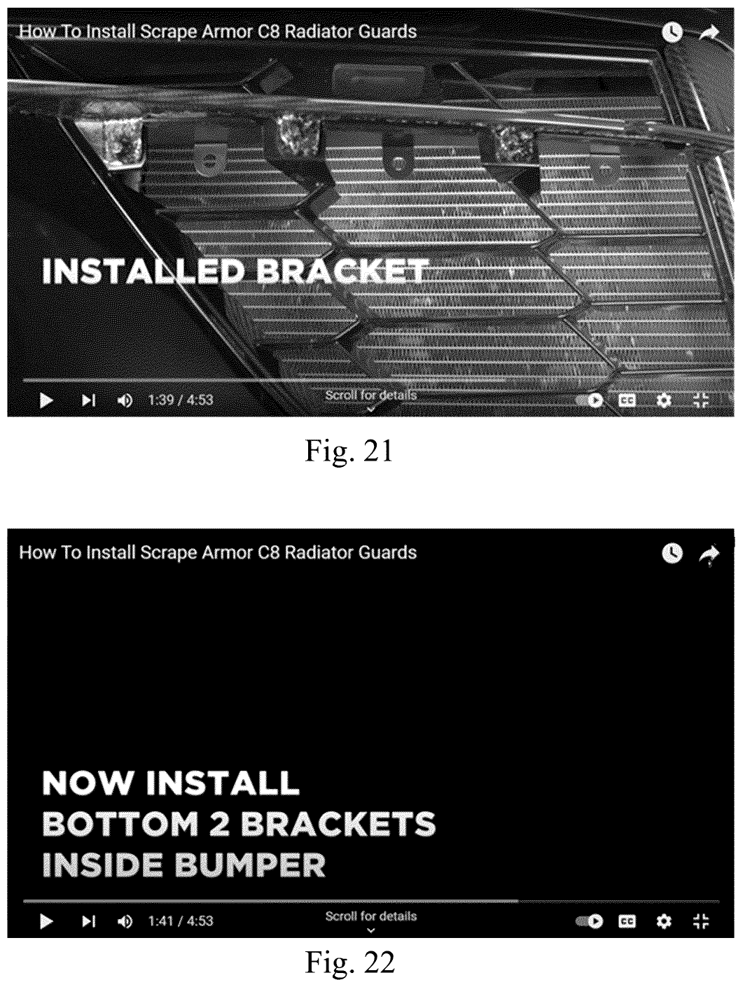

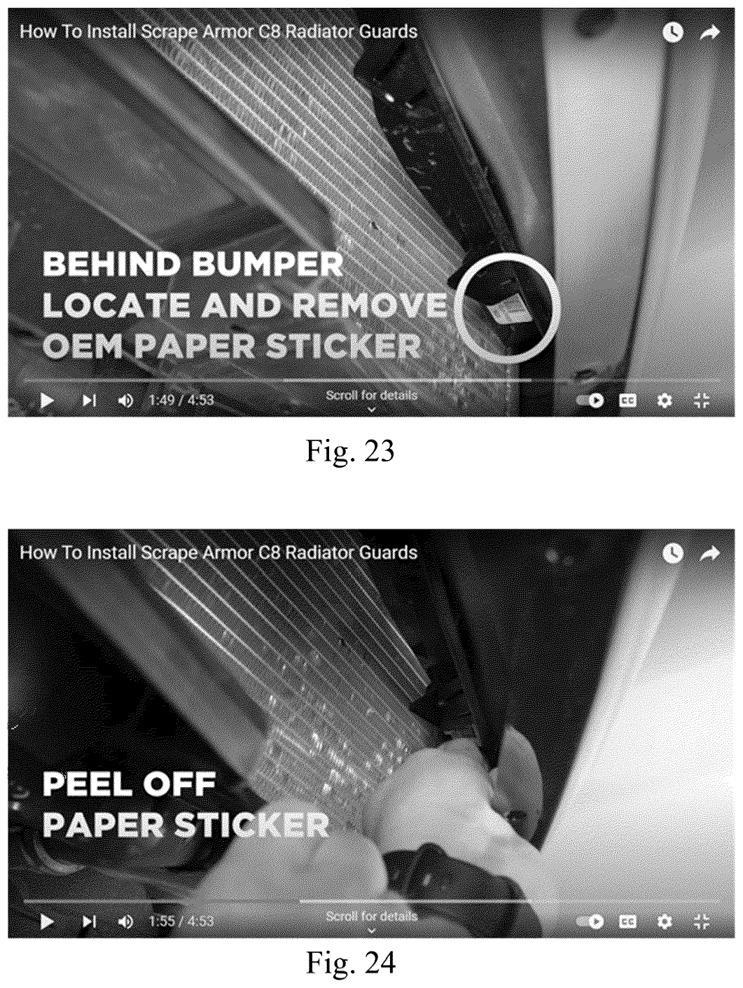

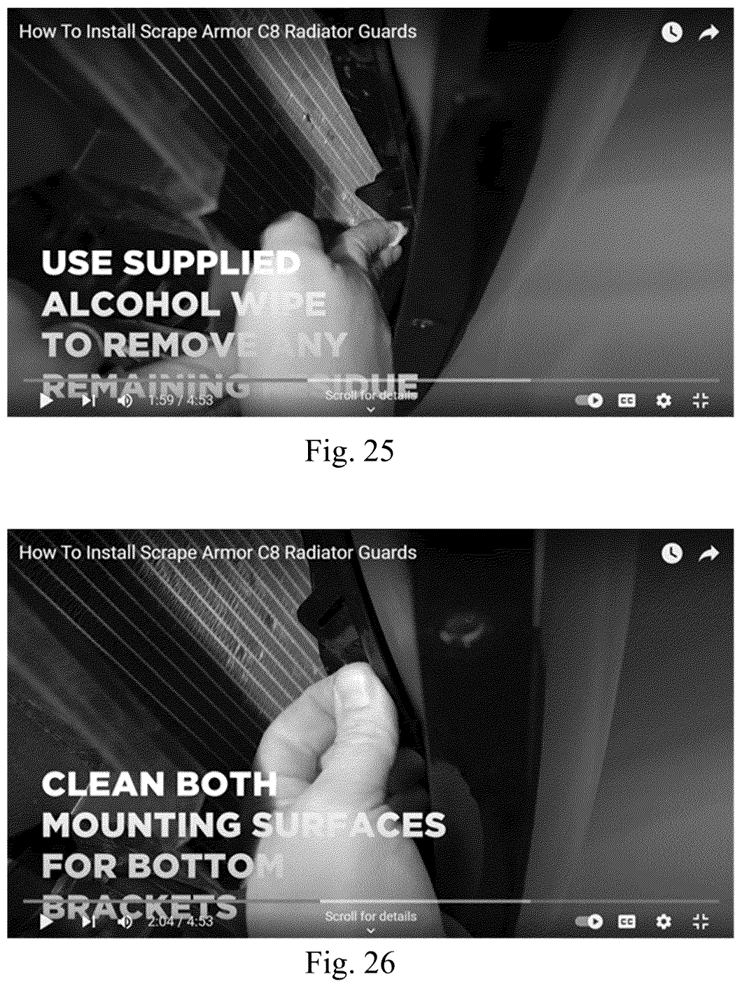

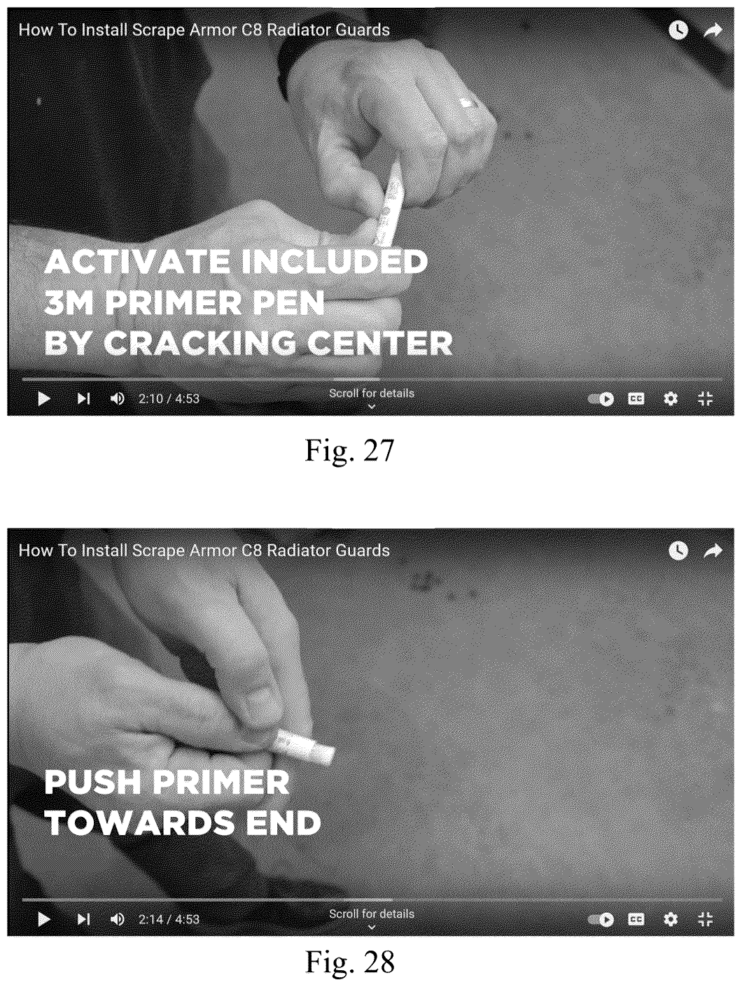

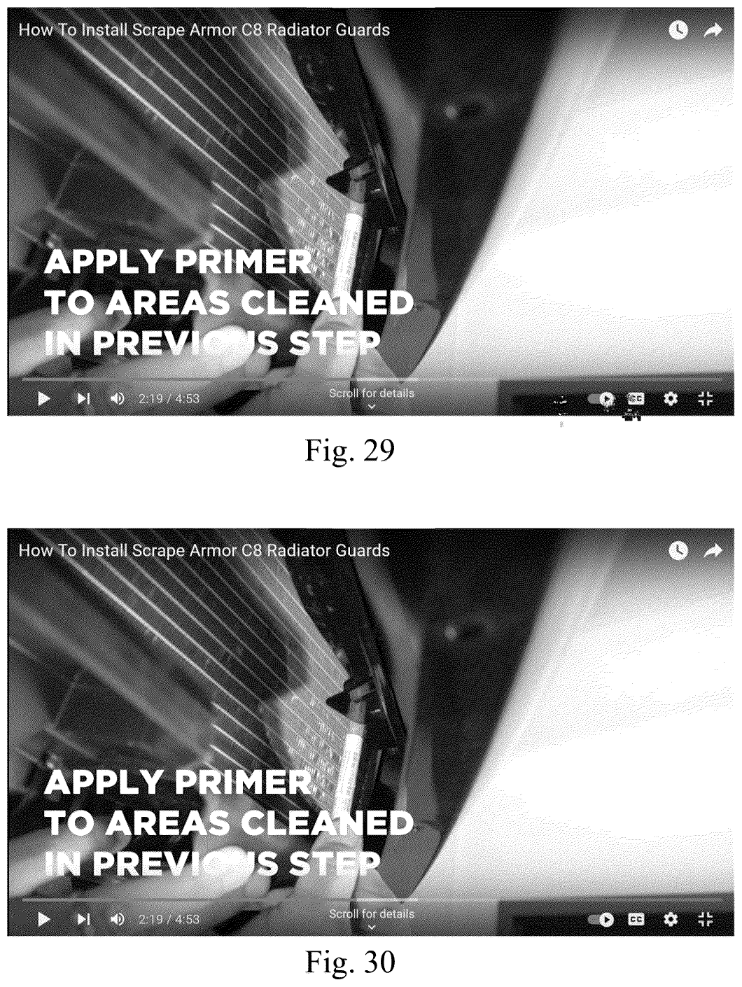

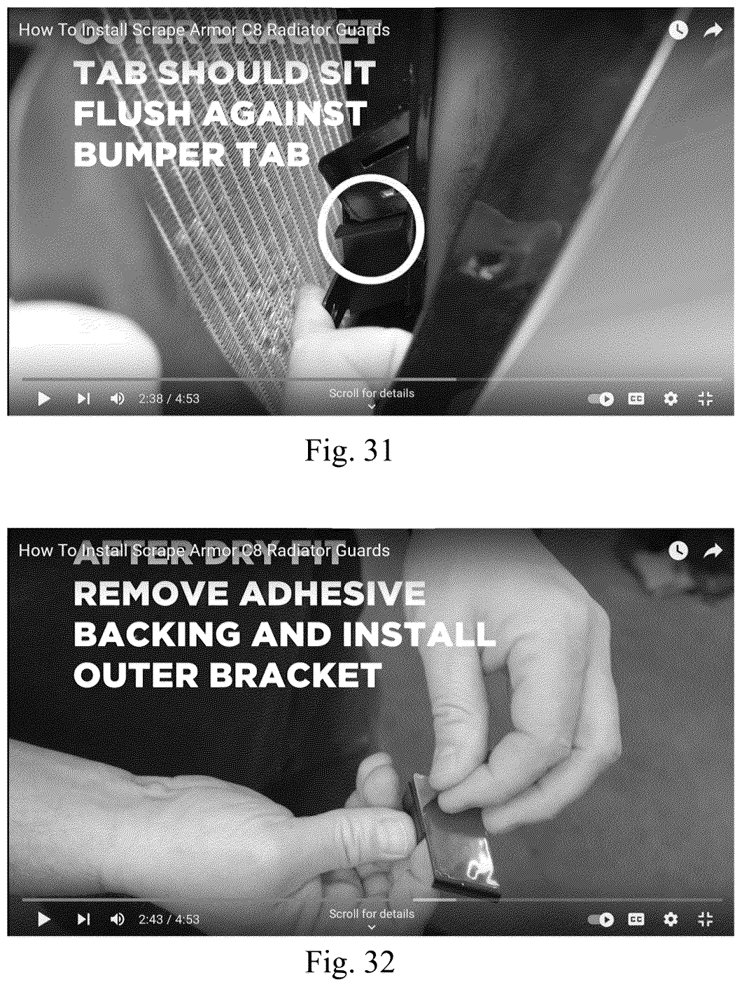

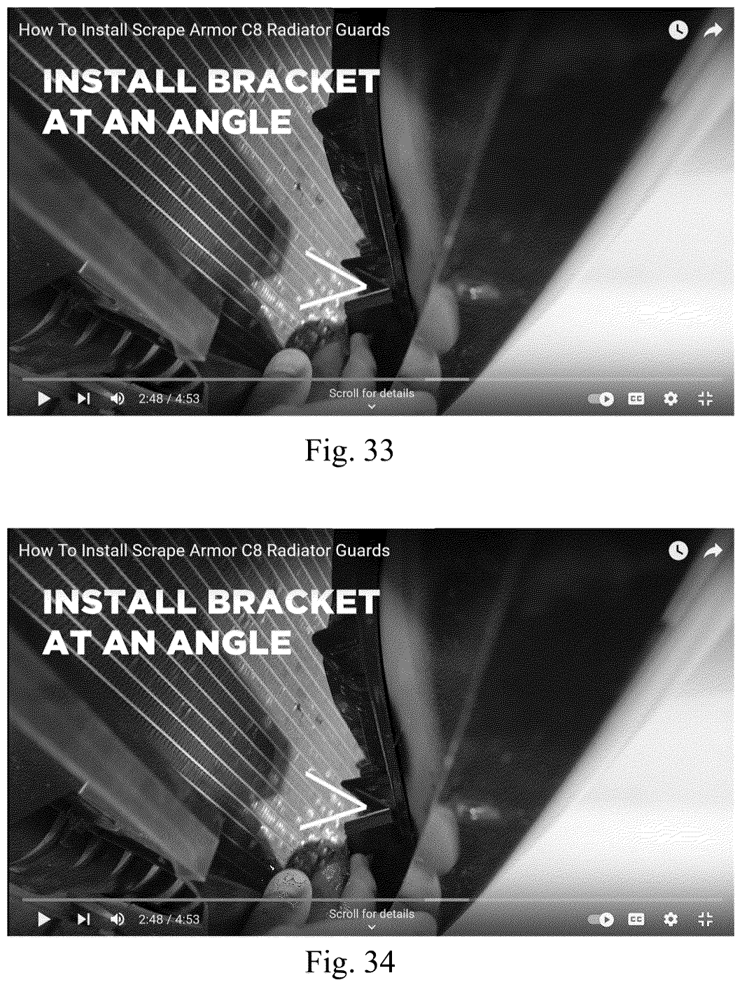

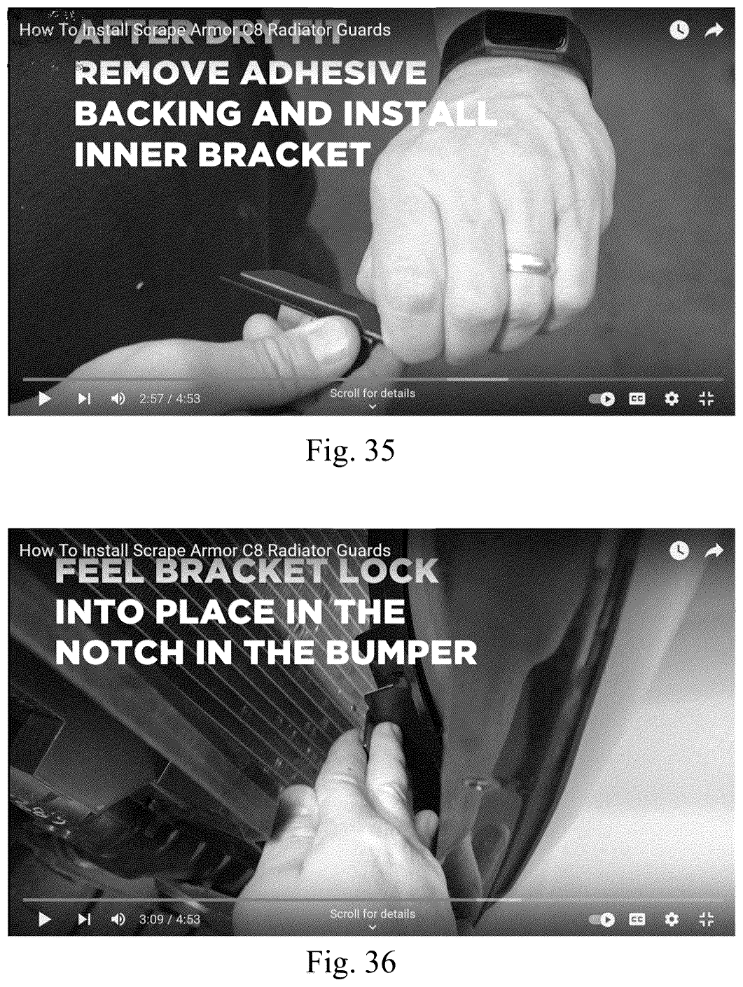

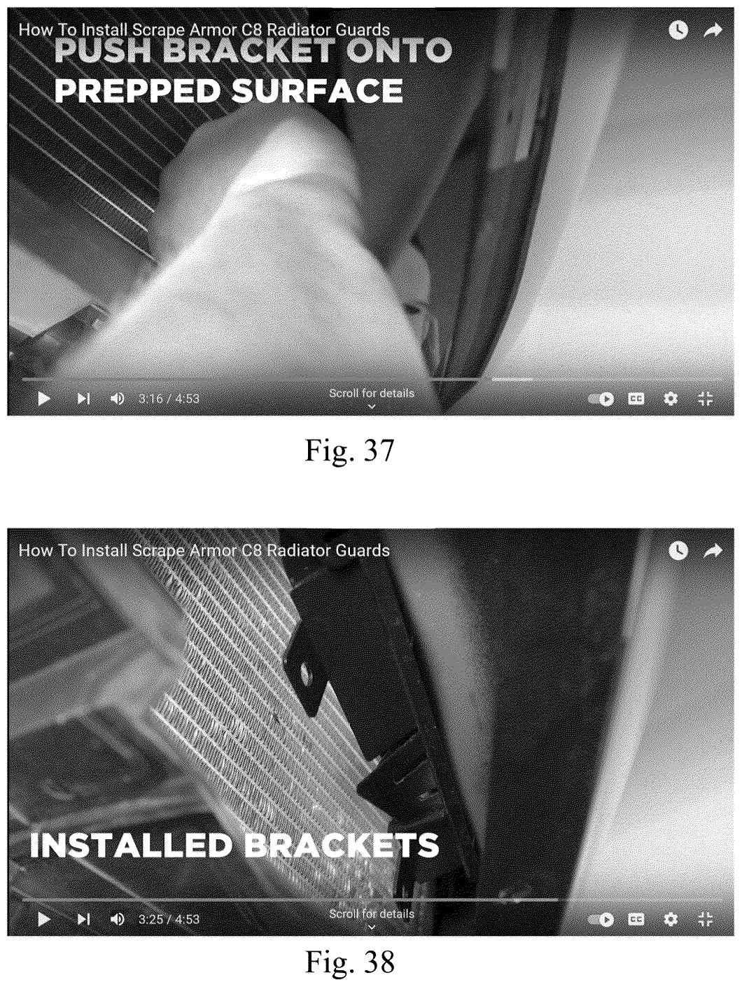

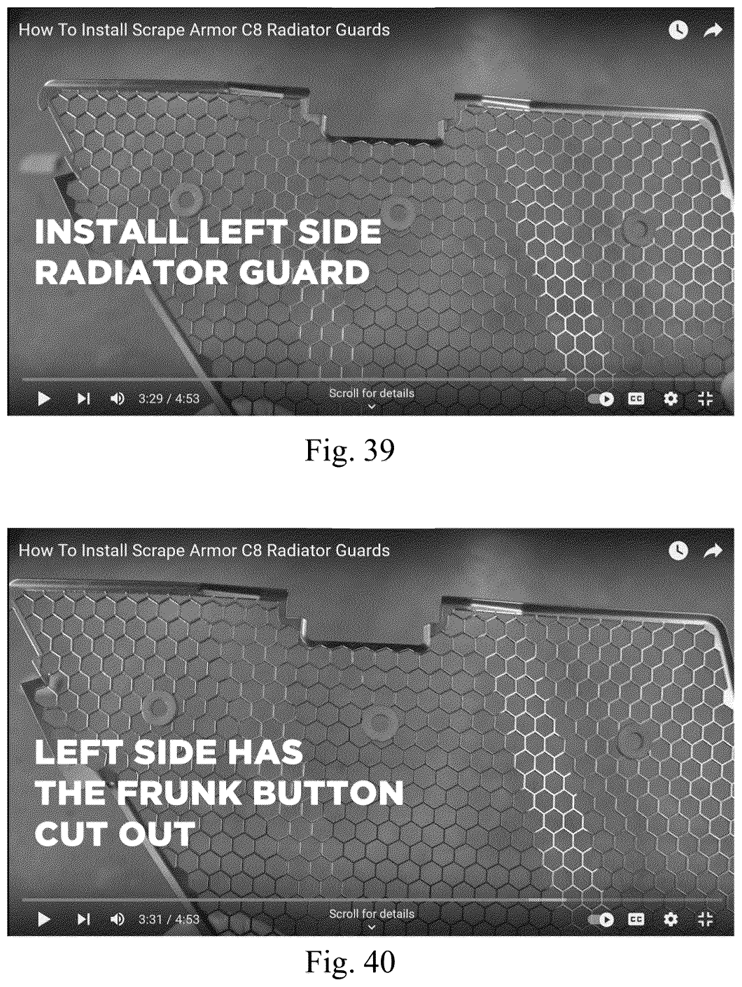

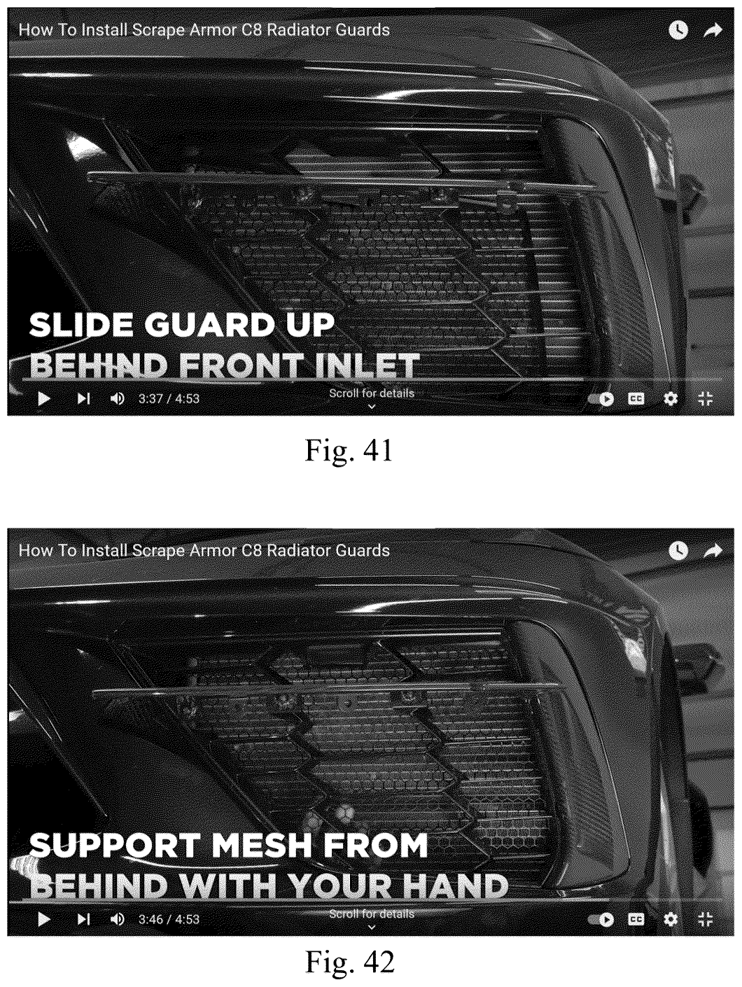

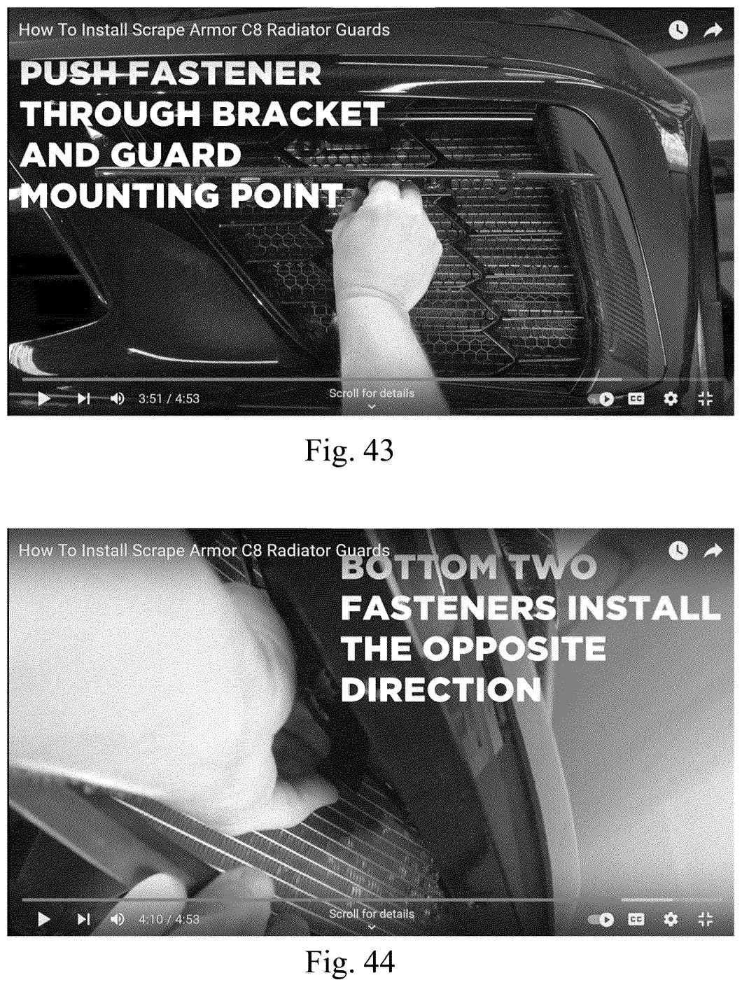

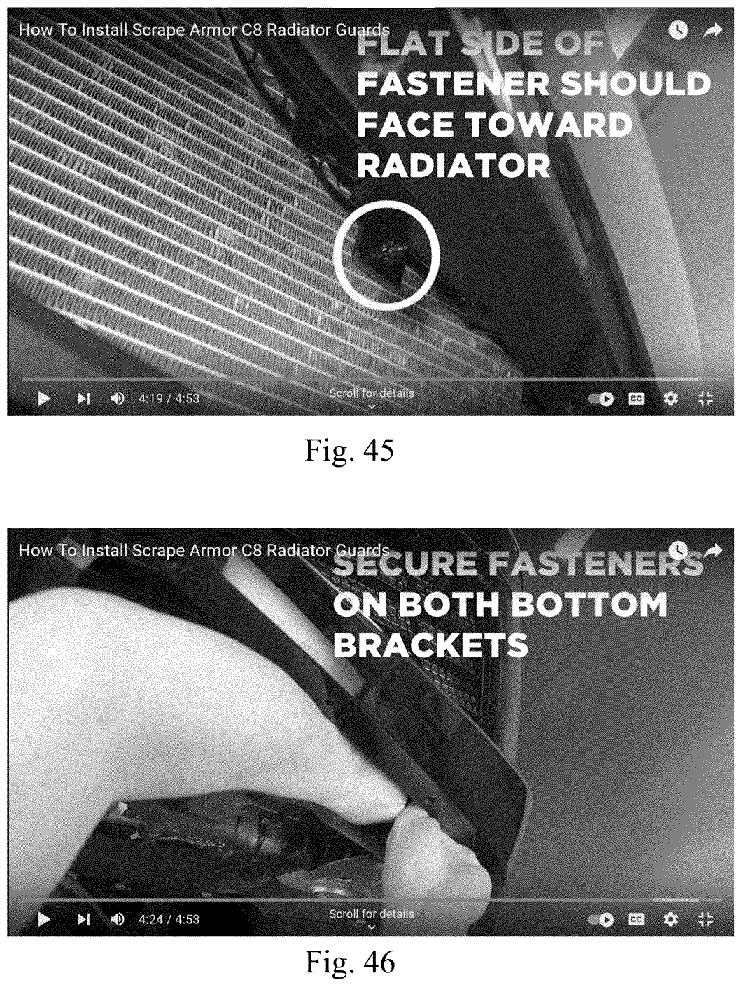

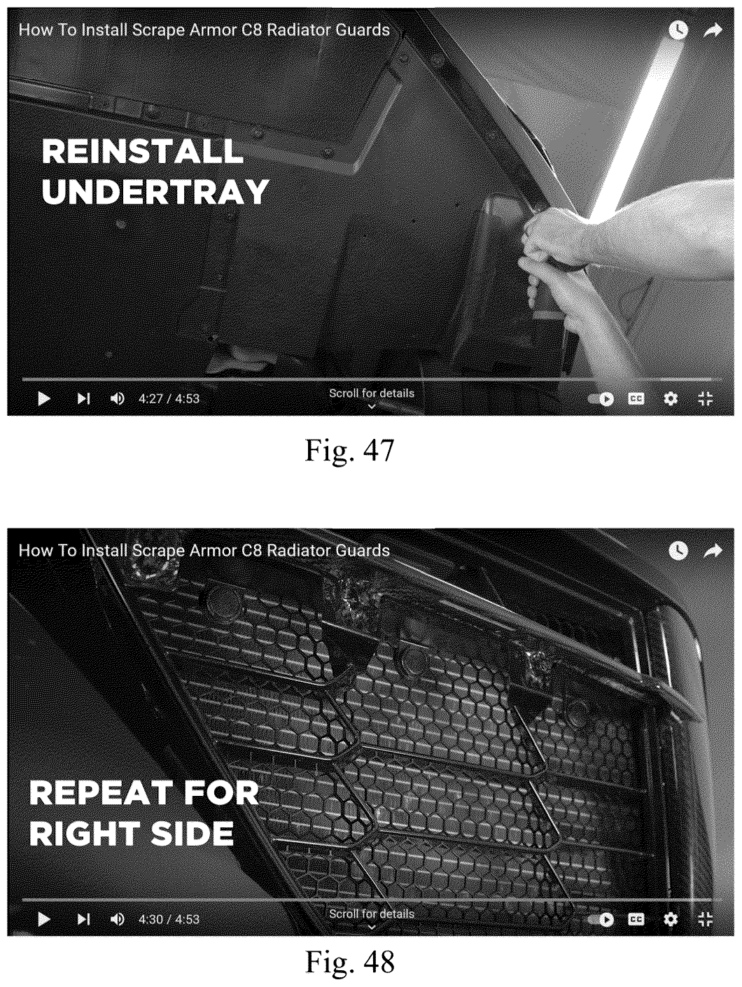

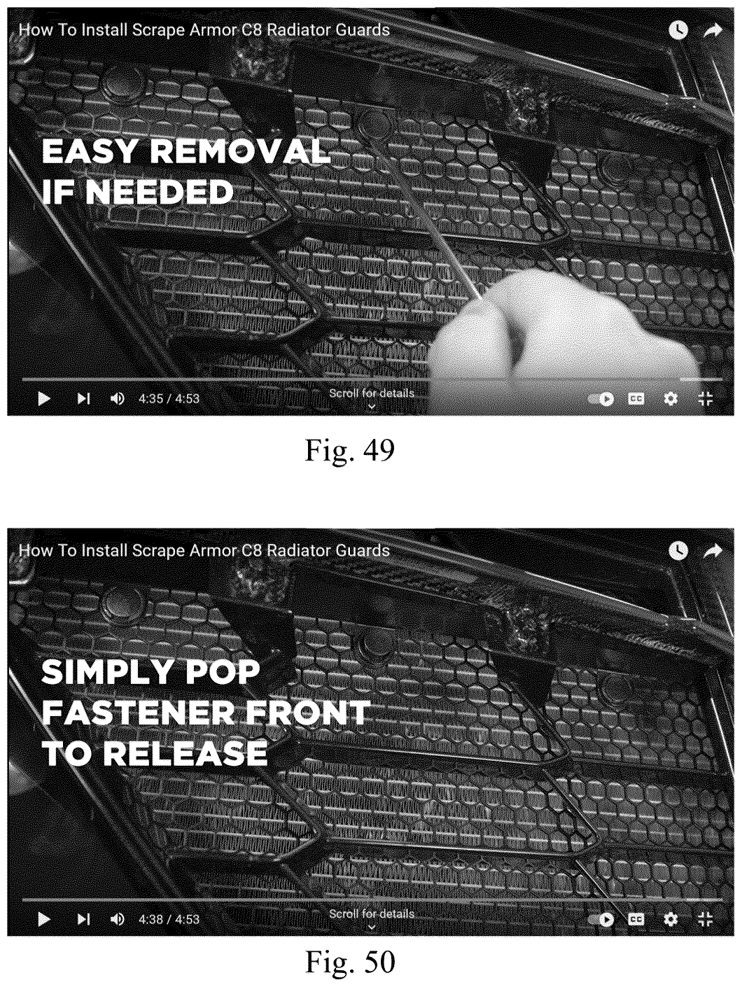

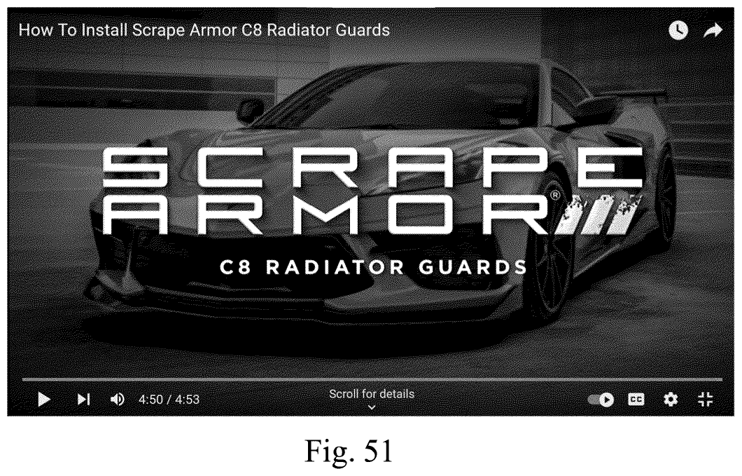

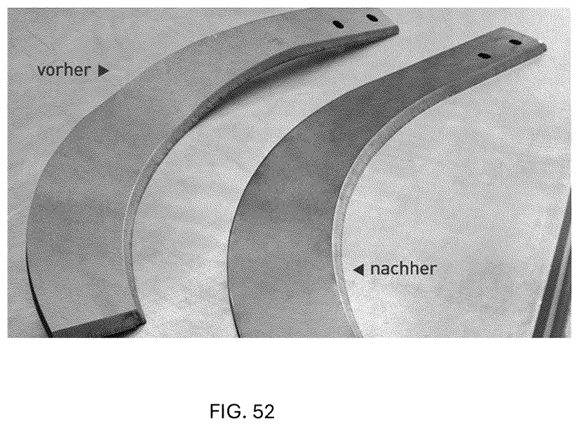

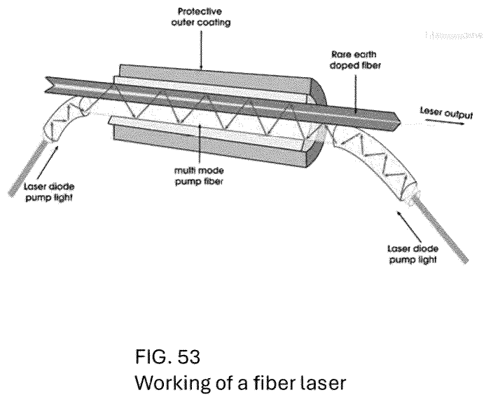

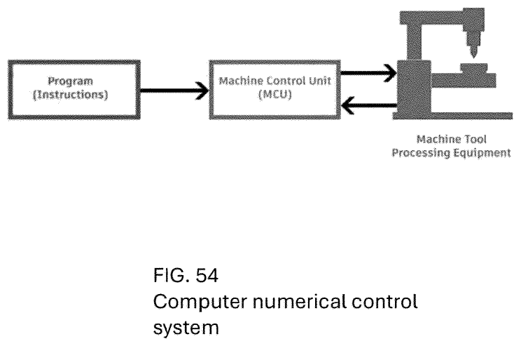

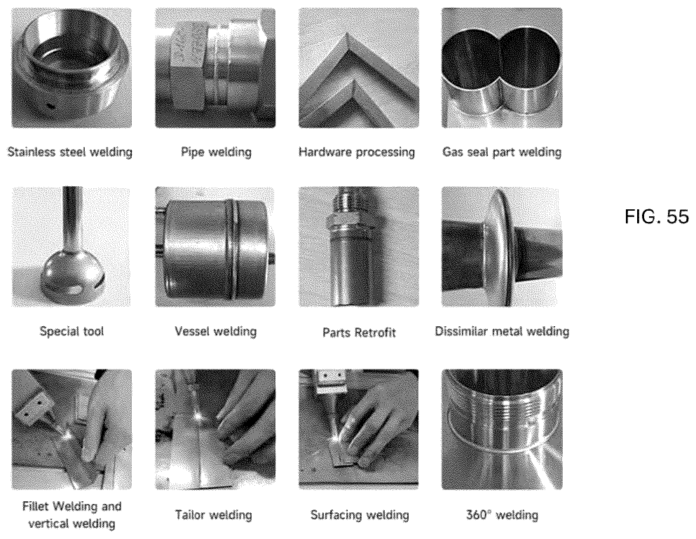

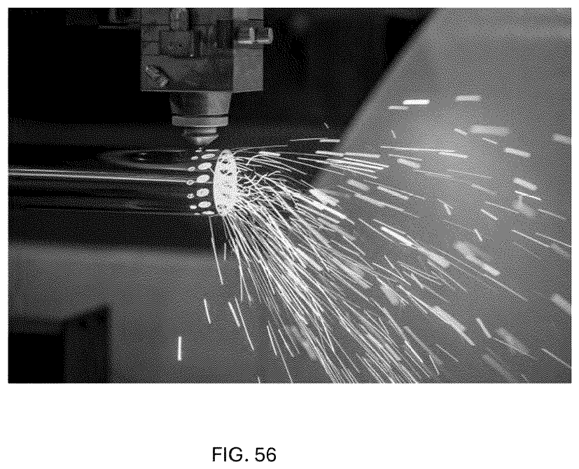

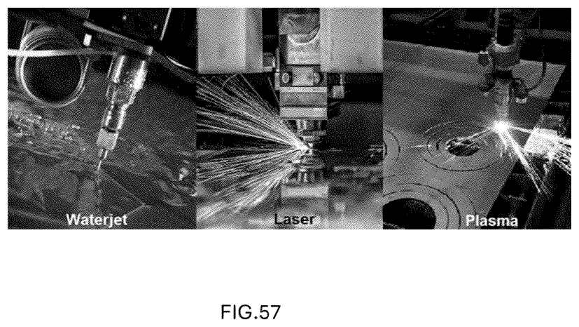

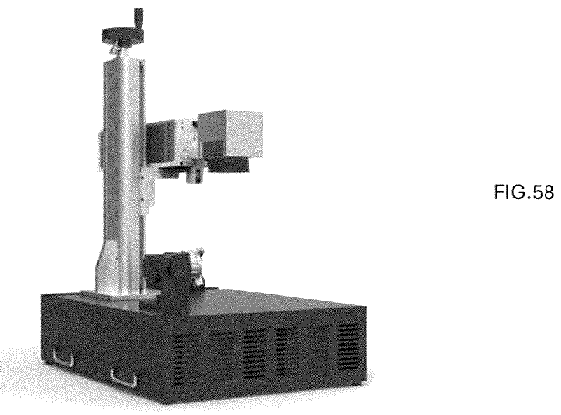

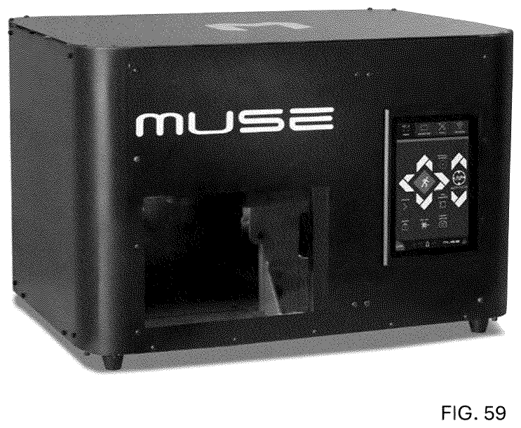

The attached Figures illustrate several: (a) perspective views according to various embodiments and (b) methods of installing certain illustrative embodiments; and (c) explanations of advantages of embodiments. Specifically, FIGS. 1-8 illustrate several embodiments of ventilated vehicle protection devices. FIGS. 9-51 illustrate a method of installing ventilated vehicle protection devices. FIGS. 52-59 illustrate equipment that can be used to manufacture the ventilated vehicle protection devices.

### DETAILED DESCRIPTION

A perforated radiator grille guard is a protective accessory designed to shield a vehicle's forward-facing radiators, which can be located in the front, side or rear grille area from various types of debris and potential damage. It consists of a metal or plastic barrier with a pattern of holes or slots (perforations) throughout its surface. Here's what it does:

Debris Protection: The primary function of a perforated radiator grille guard is to protect the radiators and heat exchangers from debris such as rocks, branches, leaves, and other objects that are present on the road while driving. These guards act as a barrier to prevent these materials from entering the areas of the vehicle where cooling systems are located, including the engine compartment and areas behind the vehicle's body work.

Cooling System Preservation: Radiators/heat exchangers are essential components for cooling various parts of a vehicles systems, including, but not limited to engine and transmission temperature, climate control systems like air conditioning and battery, charging and speed control systems for EVs and Hybrids. If debris were to damage the radiator fins or puncture the closed components for the system, it could lead to coolant leaks, ineffective heat dissipation and overheating. The grille guard helps maintain the radiator's integrity, ensuring efficient cooling.

Aesthetic Appeal: In addition to protection, some grille guards are designed to enhance the vehicle's appearance. They often come in various styles and finishes to match the vehicle's aesthetic.

Impact Protection: In some cases, grille guards can also offer limited protection in minor collisions or low-speed impacts. They absorb some of the impact force, reducing the potential damage to the vehicle's front end.

Easy Maintenance: Perforations in the guard allow air to flow freely, ensuring that the radiator continues to function efficiently. Additionally, the perforations make it relatively easy to clean the guard and remove accumulated dirt and debris.

How embodiments of an invention do it: A perforated protective screen is a barrier or shield with a pattern of holes or openings (perforations) designed to allow airflow while drastically reducing the likelihood of debris passing through them. Conceptually, they act as filters or barriers, allowing certain materials to pass through while blocking larger unwanted and potentially damaging debris.

The likelihood of a projectile passing through a perforated opening depends on several factors, including the size and shape of the openings, the velocity and size of the projectile, and the angle at which the projectile approaches the opening.

Parts, steps, and/or processes that make up embodiments of an invention: Our radiator/heat exchanger grill guards consist of some or all of the following components. (I) Perforated metal or plastic mesh panels/barriers that sit in front of the radiators, between potential projectiles and the radiators themselves. (II) Brackets/mounting fixtures that allow the mesh panels to be attached to the vehicle. (III) Hardware and fasteners necessary to attach the mesh panels to the mounting brackets and or directly to the vehicle.

How the parts, steps, and/or processes work together: In a typical application, our radiator grill guards would be designed to fit specific vehicles from either OEM design Data or data derived from reverse engineering methods such as 3d scanning.
(I) After acquisition of vehicle surface and geometry data, the perforated mesh panel design is derived from a series of considerations including but not limited to: (a) Open area, airflow calculations and testing: By definition, a perforated panel will have a percentage of “open area” as calculated by the Total Area of Perforations: (This is the combined area of all the holes, slots, or openings in the panel) divided by the Total Surface Area of the Panel: (This is the total area of the panel itself, including both the solid material and the perforated areas.) Open area is highly correlated to airflow potential and can be tested by a number of different methods including computer simulations like CFD (computational fluid dynamics), wind tunnel testing, manometer testing and real world temperature testing in extreme climates and conditions (such as race tracks in extreme temperature climates).
(i) Cosmetic integration: Our perforated mesh panel designs are developed to integrate with the cosmetic design intentions of the vehicle they are being installed on. That is, if a vehicle utilizes hexagonal geometry in other visible parts of the vehicle (perforated or not) we may develop our design around a hexagonal pattern. Same would be true for circles, diamonds, rectangles, etc. The size of the geometry itself may be different to optimize open area, but much attention is paid to the use of specific geometry and/or the spacing of the geometry, so that the end product looks cohesive with existing vehicle cosmetics.
(ii) Strength
(iii) Respect to existing components and systems
(iv) Finish
(II) After the design is developed into a product, the installation of the product onto the vehicle is normally comprised of the following steps:
(i) Brackets: In order to affix the mesh panels to the vehicle itself, mounting fixtures or brackets must either be designed into the host vehicle or added to it. If suitable locations are built into the vehicle during manufacturing, these brackets are designed from CAD Surface data, acquired by one of the methods described above) and then fitting to the vehicle by means of mechanical fasteners or adhesive.
(ii) Mesh Panels Attached to brackets: The mesh panels are then attached to the brackets. This can be done with metal or plastic fasteners such as snaps, bolts and nuts, screws, clips, ties, etc. or various types of adhesives.

Preferably, one can use design data/CAD models of the parts of the vehicle we are working on, to design our products to fit specific models of vehicles. This data is preferred or acquired either via digitizing equipment like 3D scanners and subsequently reverse engineered, or in some cases is provided by the vehicle manufacturer.

Preferably, we use a number of software tools in the design and manufacturing process, including: Design-Auto CAD, Fusion 360, Rhino 3D, Mesh2 Surface, VX Elements, CNCKAD. Manufacturing-Fusion 360, CNCKAD, Cypcut, ULS Laser Control, VCarve Pro.

Methods of Manufacturing that Enable Efficient Scale Production

### Step 1—Punching Perforated Mesh Panels:

Starting with a solid sheet of material with no holes/perforations in it, we load a sheet/“blank” into a CNC punching machine and perforate it in the pattern specified by the design. (See attached description of CNC Punching Machine.)

### Step 2A—Wash Punched Blanks

The CNC Punching process uses petroleum-based oil to lubricate the punch passing through the “blank.” This oil must be removed by cleaners for subsequent processes.

### Step 2B—Flattening

The CNC punching process introduces stress into the material/blank, which stretches/deforms it. This deformation is called “oil canning”.

“Oil canning” is a term used in the context of sheet metal and refers to a phenomenon where the metal surface appears wavy or distorted, resembling the shape of an old-fashioned oil can. This distortion typically occurs when the sheet metal panel is subjected to uneven stresses, which can result in localized bulging or flexing of the metal. Oil canning is generally considered an undesirable effect in sheet metal applications, as it can affect the appearance and structural integrity of the metal component.

In order to correct this, the blank must be passed through a machine that removes the stress and flattens the material, called a leveler. Businesses, industries and commerce primarily focus on three things: quality, delivery time and efficiency. Only companies in control of their processes will successfully prevail against the competition over the long term. The same applies to the metalworking industry. Raw materials in ideal condition for further processing are a key factor here. However, sheets are often out-of-flat and have internal stresses. These defects impair the efficiency of downstream processing. That is why leveling the parts after processing, for example laser cutting, is essential. Read this article and find out all about leveling sheet metal along with the factors you need to consider.

Out-of-flat sheets with internal stresses impair efficiency.

Stress-relieved sheets are essential for all downstream production processes in sheet metal fabrication. However, internal stresses are an almost inescapable byproduct of the processing. Laser cutting in particular is notorious for creating and releasing these stresses. The cutting laser generates a vast amount of heat where it hits the material. This, in turn, creates a massive temperature gradient resulting in internal stresses. In addition, this cutting process also hardens the edges. The consequence: deformed parts. These are problematic when it comes to efficient downstream processing. The only solution: you have to level the sheets.

Leveling sheets which are about to be laser cut is important in order to minimize scrap and the amount of effort involved in rework. The objective is to significantly reduce both internal stresses and flatness defects. Roller leveling is a proven approach in this regard. But remember: not all roller levelers are made equal. Specific characteristics and features of the machines ensure consistent leveling quality. These include the block design of the leveling unit, the correct roller configuration, the amount and quality of the support rollers, and the number and diameter of the leveling rollers. Small leveling rollers, a small roller pitch, a large number of leveling rollers, and very good support are essential to fulfill the demanding flatness requirements.

Leveling sheet metal with the roller leveler—How it works.

In the field of forming technology, roller leveling generally refers to a bending process using rotating tools. In other words, roller leveling is a bending process that utilizes rollers. It is an excellent means of rapidly and easily flattening sheet metal. This approach reduces the stresses and flatness defects by means of elastic-plastic alternating bending. When using a roller leveler, the panels run through a series of alternating bends. The machine's leveling rollers are arranged with an offset from the infeed to the outlet. As a result, a roller can always sit in between two opposite rollers, subjecting the material to large and then progressively smaller alternating bends. This bending process resembles a diminishing sine wave.

The alternating bending movements when using a roller leveler achieve flat parts which are nearly free of internal stresses. This is critical for efficient and problem-free downstream processing. It is important that the bending of the part at the machine infeed is larger than the largest existing bend. This is the only way to ensure that the alternating bending has optimum sufficient effect on the material being leveled. The leveling process eliminates the internal stresses and flatness defects, creating a leveled part. At the same time, the roller leveler has no effect on flat sections of the part. These remain unchanged.

Roller leveling for greater efficiency.

Roller leveling is the cost-effective approach for material thicknesses between 0.1 mm and 50 mm (0.004″-2″). Panels with reduced internal stresses can generally be leveled in one run in a matter seconds. Multiple runs may also be necessary depending on the geometry. Yet even if a part has to be run through the leveler twice, roller leveling is still a rapid and, thus, cost-effective process. For example:

Imagine that you had to level 30,000 parts per year. Manual leveling carried out by an employee with a press brake would require 10 minutes per part. In contrast, a roller leveler completes the task in less than one minute. At a cost of $65 per hour for the manual leveling and $150 per hour for machine leveling, this would deliver a cost reduction of $250,000 per year. A quarter of a million simply by leveling your parts with the proper machine. It is obvious that roller leveling represents a simple, rapid and, above all, economical approach to sheet metal leveling in comparison to other methods.

Leveling sheet metal and achieving the highest quality.

In addition to the cost aspect, the quality of manual sheet metal leveling can also be a disadvantage. People are not machines. Their working processes cannot be 100% standardized and therefore no two parts will have the same flatness results. Leveling manually, which relies on human capabilities, cannot guarantee consistent quality. Additionally, the specialists who can accomplish this task are also rare. In comparison, a roller leveler ensures reliable results. The leveler should also ideally be equipped with overload protection to guarantee a long service life. Hydraulic systems have proven their value in this regard. These hydraulics enable a safe work environment while dealing with extreme forces. They also enable essentially wear-free leveling gap control. These systems hold the machine in position during the leveling process, regardless of the forces generated. This ensures the best-possible results.

All of the characteristics of high-quality levelers combine to ensure rapid and good quality leveling results with reliable processes. Modern roller levelers automatically calculate the right settings so that the operator only needs to make minor corrections. Machines are now also capable of checking the flatness, which enables automated leveling for numerous applications.

Eliminate internal stresses to create high-quality part.

In summary, leveling parts with a roller leveler is one of the fastest, easiest and cost-efficient methods of leveling. It ensures high-quality sheet metal parts. This is a key factor for sheet metal processing.

See https://www.arku.com/en-us/arku-magazine/detail/leveling-sheet-metal-eliminate-stress-us/#:˜:text=The%20machine's%20leveling%20rollers%20are,resembles%20a%20diminishing% 20sine%20wave.

### Step 3—Laser Operations

The CNC punch is only capable/efficient of making through-holes in the blank material of the geometry and size of the punch itself. Because the geometry of the parts we make is organic and must be so to fit the existing geometry of the vehicle, many of the perforations we need to make around the outside edges and mounting areas of the mesh panel. The organic shape of the perimeter of the part must also be efficiently cut out of the blank.

To do this we use a tool called a CNC fiber laser. CNC Fiber Laser—Explained

Numerical Control (NC) is a conventional method of programming machines to produce parts at speed and scale.

Computer Numerical Control (CNC) is an upgrade to Numerical Control, allowing you to automate machine tools with the help of software and machine controller units.

It helps fasten up the manufacturing process and allows the flexibility of revisions in programming a machine.

CNC technology is more precise, requires less human intervention, easy to program, and is economical.

Fiber lasers are named after their active gain medium, the optical fiber. They are solid-state devices that produce high-power and well-collimated laser beams from low-speed raw light.

A CNC fiber laser is a fiber laser machine integrated with CNC technology.

Today most fiber lasers are CNC-integrated. So generally, a CNC fiber laser is addressed as a fiber laser.

How does a CNC Fiber Laser Work?

In a CNC fiber laser, a fiber made of glass or phosphate absorbs raw light from pump diodes.

Then the light is simulated and amplified, converting it into a highly collimated laser beam of a predefined wavelength.

These optical fibers are doped with rare earth elements to optimize the laser beam output.

Some common rare-earth elements and the laser wavelength they produce are given in the table below. (nm=nanometer)

| Rare earth element | Wavelength of laser | |
|---|---|---|
| Neodymium | 780-1100 | nm |
| Ytterbium | 1000-1100 | nm |
| Praseodymium | 1300 | nm |
| Erbium | 1460-1640 | nm |
| Thulium | 1900-250 | nm |
| Holmium | 2025-2200 | nm |
| Dysprosium | 2600-3400 | nm |

Elements doped with a fiber laser and their wavelength range

The generated laser beam is then sent to a computer-controlled laser head that is moved along different axes with the help of actuators.

You can program this machine to follow a specific path to make the desired part.

### Types of Fiber Lasers

Fiber lasers are classified into many types based on their laser source, operation, power, and core diameter.

These classifications of the laser help map your expectations to select a suitable laser for your needs.

### Based on The Laser Source

Depending on the doping material used on the fiber laser medium, there are many fiber lasers.

For example, the Ytterbium-doped fiber laser gives a 1060 nm wavelength laser output suited for welding jobs.

A CO2 laser has an average wavelength of 10 μM, which limits the materials it can work with. It cannot readily work with reflective materials like metals.

On the other hand, fiber lasers can be used on various metals like aluminum, steel, copper, brass, etc.

Another popular laser in the market is the diode laser, which uses the light directly from a semiconductor diode, eliminating the need for doped rare-earth materials.

Diode lasers also have a similar wavelength as fiber lasers and have the highest efficiency of 50% electricity conversion.

But the biggest disadvantage of diode lasers is that they produce more divergent beams, which are less focused and can't handle metal very well.

So if you are more into working with metals, a fiber laser machine is your best bet.

The initial investment for a fiber laser would cost around $15,000 and can go up to $1,000,000, sometimes, even more, depending on the machine's power rating and feature combinations.

But, the investment is a wise one because the average lifetime of a commercial fiber laser would be around 30,000 hours.

Comparatively, diode and CO2 lasers have lower costs, but the maximum lifetime you can expect is 2,000 hours which results in fast recuring replacement costs.

### Alternatives to Fiber Laser

Some popular alternatives to fiber laser cutting are flame cutting, waterjet cutting, and plasma cutting.

### Flame Cutting

Flame cutting involves cutting the materials with an oxy-fuel torch. It uses pure oxygen to combust the fuel, oxidizing and cutting the material.

One big disadvantage of flame cutting is that it can oxidize any region of the exposed material, affecting its performance.

### Plasma Cutting

Plasma cutting uses an electric arc passed through a gas to form a concentrated electric beam to cut materials.

The electric arc generates heat on the material surface, which is used to cut the material. It demands more electricity than fiber lasers for its operations.

### Water Jet Cutting

Water jet cutting is one of the earliest methods of metal cutting. It forces high-pressure water onto the material surface, accelerating material erosion and cutting it through the water jet path.

It can cut harder and thicker materials than fiber lasers.

### Best CNC Fiber Lasers

The following machines are some of the best fiber lasers commercially available for anyone to get.

### BOSS FM Desktop

FM Desktop from Boss Laser is available in 20 W, 30 W, and 50 W output power options. It has a rated lifetime of 100,000+ hours.

The beam quality from 20 W and 30 W FM desktop lasers is less than 1.5 M2. For the 50 W model, it is less than 1.8 M2.

M2 is called the beam propagation ratio, which measures the laser beam's focus quality. When the M2 value gets closer to one, the laser spot colligates to a tighter spot.

Beam quality is important in the efficiency of laser cutting. The higher the beam quality, the higher the precision of the laser, and the lesser time it takes to complete a job.

FM desktop is a mobile laser engraver and is ideal for small projects. It has a non-adjustable XY axis and an adjustable Z axis.

It is ideal for engraving jobs on materials like plastic, acrylic, PVC, granite, marble, aluminum, silver, brass, etc.

FM desktop comes pre-assembled. It is provided with lifetime technical support and a standard 2-year parts warranty from the company.

### FSL Muse Pandora

The FSL Pandora fiber laser is available in 20 W, 30 W, and 50 W output power options. They have an average lifetime of 25,000+ hours.

It can work with metals like titanium, steel, etc., and organic materials like leather.

FSL offers this machine in different work area sizes, but they all have the same footprint. The maximum work area you can get is 11.3″×11.3″.

The laser head on pandora is stable and can't move along the XY axes. It uses a galvo head to change the focused laser beam position in the work area.

Pandora works with the manufacturer's proprietary software, RetinaEngrave v3.0. It runs on a web interface and can be worked on most devices.

FSL provides a 1-year warranty for the machine. Depending on your chosen machine configuration, you might need to put together the machine.

### Check Price on FSL

### Final Thoughts

A CNC fiber laser is an efficient, true-to-value product for processing metal workpieces. It also provides longer life than other types of lasers.

They are largely employed in metal-cutting and engraving jobs. Since the laser beam has an active focus plane, CNC fiber lasers are best at processing sheet metals.

If your jobs are more slanted toward engraving, marking, or etching metals, get a machine having a galvo head. It allows the laser beam to cover a larger material surface area in less time.

In a standard CNC fiber laser, you can also control laser parameters like output power, cutting speed, focus depth, etc., to adjust the processing conditions.

### Frequently Asked Questions

How much thick material can a fiber laser cut?

A standard fiber laser can cut materials of up to 10 mm thickness. It depends on the laser power and lens used to focus the laser. A high-powered fiber laser is best for cutting jobs.

What are the precautions to be followed for using a fiber laser?

When using a fiber laser, ensure everyone near the machine is wearing a laser safety glass. Otherwise, it can cause permanent damage to the eyes. Also, ensure that the parameters you set are tested and verified for the material. If not, it can cause fire hazards.

Fiber lasers are a popular machine tool in manufacturing. It is primarily used to work with metal workpieces and requires less maintenance.

CNC fiber laser is a CNC machine that generates a laser beam and passes it through a fiber optic cable wired to a computer-controlled laser head. It then focuses the laser beam on a narrow spot with a series of lenses, allowing it to cut and engrave different materials.

This article discusses CNC fiber laser in detail by looking at its working, types, application, alternatives, and best machines in the current market.

See https://mellowpine.com/cnc/cnc-fiber-laser/#:˜:text=It%20is%20primarily%20used%20to,a%20computer%2Dcontrolled%20laser%20 head.

The challenge with this is that in order for the Fiber laser cut-outs to perfectly blend into the design of the punched part, they must be oriented and located with very high accuracy into the machine, so that the laser work blends perfectly with the perforations the punch has already made and the processes are indistinguishable in the final part.

Precisely locating this part in the laser requires a “fixture” which the laser can identify the exact position of. This fixture must be designed so that the punched blanks can be quickly and accurately located on the fixture.

We do this punching index holes in the blank, outside the parts design geometry which are then correlated to index holes or pins in the fixture.

The fiber laser then does all of the partial perforations and cuts out the part perimeter.

### Step 4—Deburring

The punch and laser trimming process above leaves small burrs or undesirable sharp edges on the backside of the material. These edges must be removed so that a quality finish can be applied. Additionally, the effectiveness of a finishing process, called powder coating is greatly enhanced by sucking up/sanding the surface of the part to create a mechanical tool for the finish to bond to.

In order to remove the burrs and create mechanical tooth for the finishing proses, the punched, laser trimmed and flattened parts are then sent through a conveyor belt drive sanding machine that uses either abrasive belts or abrasive rotating brushes.

### Step 5—Forming

All of the prior processes are completed while the material is still a 2 dimensional/flat part. The finished parts then preferably needs to be formed into a 3D Dimensional part. To do this the deburred parts are precisely located in between a male and female set of forming dies.

The forming dies are mounted in a hydraulic press. When pressure is applied, the male and female dies are pushed together and the prat between them is then formed to the surface shape of the dies.

This is normally done with hardened steel forming tools and expensive, large industrial presses. Because the material we use is thin and perforated, we are able to design and machine the tooling for our parts in house, from a Urethane composite board. While the urethane board does not last as long as hardened steel tooling due to it being softer and wearing faster, we can easily remove a small amount of the surface contour on our in-house equipment and effectively “sharpen” the forming dies many times before needing to replace them.

Utilizing urethane forming tools and making/servicing them in house radically reduces both the cost and time to market of our products.

### Step 6—Apply the Finish

Our parts are then finished by a process called powder coating. Please see description at: https://www.powdercoating.org/page/WhatIsPC. The quality and longevity of a powder coated finish is heavily influenced by the preparation procedure of the part prior to coating. Our parts are in high impact areas of the vehicle, so good adhesion is very important. This is why we deliver the parts to our powder coater with “mechanical tooth” and why our powder coater uses a 5-step process to ensure good adhesion. See https://www.precisioncoatingtech.com/blog/5-stages-of-powder-coating/.

Although the foregoing text sets forth a detailed description of numerous different embodiments, it should be understood that the scope of protection is defined by the words of the claims to follow. The detailed description is to be construed as exemplary only and does not describe every possible embodiment because describing every possible embodiment would be impractical, if not impossible. Numerous alternative embodiments could be implemented, using either current technology or technology developed after the filing date of this patent, which would still fall within the scope of the claims.

Thus, many modifications and variations may be made in the techniques and structures described and illustrated herein without departing from the spirit and scope of the present claims. Accordingly, it should be understood that the methods and apparatus described herein are illustrative only and are not limiting upon the scope of the claims.

What is claimed is:

1. A method of manufacturing a ventilated vehicle protection device comprising:
a. Punching a perforated mesh panel using a lubricant;
b. Washing the lubricant from the perforated mesh panel that has been punched;
c. Flattening the punched and washed perforated mesh panel;
d. Perforate a perimeter of the panel with a laser;
e. Debur the panel;
f. Press form the panel in three dimensions; and
g. Apply a finish to the panel.
